(19) United States
(12) Patent Application Publication
(10) Pub. No.: US 2026/0353604 A1
(43) Pub. Date: Nov. 5, 2026

(54) SUB-ATMOSPHERIC LIQUID SUPPLY SYSTEM

(71) Applicant: Nortek Air Solutions Canada, Inc., Saskatoon (CA)

(72) Inventors: Christopher Regier, Saskatoon (CA); Philip Paul LePoudre, Shields (CA); Syed Wajih Hassan, Calgary (CA)

(21) Appl. No.: 19/488,492

(22) PCT Filed: May 30, 2024
(86) PCT No.: PCT/CA2024/050723

§ 371 Date: Nov. 26, 2025

Related U.S. Application Data
(60) Provisional application No. 63/469,749, filed on May 30, 2023.

(51) Int. Cl. H05K 7/20

(52) U.S. Cl. CPC H05K 7/20272; H05K 7/20281; H05K 7/20763; H05K 7/20836

(57) ABSTRACT

A method can include receiving and storing, with an atmospheric reservoir, a cooling liquid from a cooling liquid source. Directing the cooling liquid from the atmospheric reservoir to an inlet of a data center cooling system. Receiving, with an inlet of a sub-atmospheric reservoir, the cooling liquid from an outlet of the data center cooling system. Controlling an inlet pressure at the inlet of the data center cooling system with a control valve. The control valve can be installed between the atmospheric reservoir and the inlet of the data center cooling system. Controlling an outlet pressure at the outlet of the data center cooling system with a pump. An inlet of the pump can be fluidically connected to an outlet of the sub-atmospheric reservoir. The inlet pressure of the data center cooling system can be greater than the outlet pressure of the data center cooling system.

### CLAIM OF PRIORITY

This patent application claims the benefit of priority, under 35 U.S.C. Section 119(e), to Christopher Regier U.S. patent application Ser. No. 63/469,749, entitled “SUB-ATMOSPHERIC LIQUID SUPPLY SYSTEM,” filed on May 30, 2023 (Attorney Docket No. 5991.082PRV), which is hereby incorporated by reference herein in its entirety.

### TECHNICAL FIELD

Examples described herein generally relate to a liquid supply system. More specifically, the examples described herein generally relate to a sub-atmospheric liquid supply system.

### BACKGROUND

The need for liquid handling, and more specifically, liquid handling for the cooling of data centers, is increasing as the cooling requirements of data centers increase with advancements in data center processing capabilities and technology. As the cooling requirements have increased, data centers have moved from air to liquid cooling systems. The inventors of the present disclosure have devised a solution to provide better cooling capacity to data centers and mitigate risk to the data center if the cooling system leaks.

### SUMMARY

In an example, a sub-atmospheric liquid supply system can include an atmospheric reservoir fluidically connected to a working liquid source from which it can be configured to receive and store a working liquid at or above atmospheric pressure. The atmospheric reservoir can be fluidically connected to and configured to provide the working liquid to an inlet of a liquid system. A sub-atmospheric reservoir can have an inlet fluidically connected to an outlet of the liquid system. A control valve can be fluidically connected between the atmospheric reservoir and the liquid system. The control valve can be configured to decrease a pressure of the working liquid below atmospheric pressure to control an inlet pressure at the inlet of the liquid system. A pump can be fluidically connected to an outlet of the sub-atmospheric reservoir. The pump can be configured to control an outlet pressure at the outlet of the liquid system. The inlet pressure of the liquid system can be greater than the outlet pressure of the liquid system.

In an example, a sub-atmospheric direct liquid cooling supply system can include an atmospheric reservoir that can be fluidically connected to a cooling source from which it can be configured to receive and store a cooling liquid at or above atmospheric pressure. The atmospheric reservoir can be fluidically connected to and configured to provide cooling liquid to an inlet of a data center cooling system. A sub-atmospheric reservoir can have an inlet fluidically connected to an outlet of the data center cooling system. A control valve can be fluidically connected between the atmospheric reservoir and the data center cooling system. The control valve can be configured to decrease a pressure of the cooling liquid below atmospheric pressure to control an inlet pressure at the inlet of the data center cooling system. A pump can be fluidically connected to an outlet of a sub-atmospheric reservoir. The pump can be configured to control an outlet pressure at an outlet of the data center cooling system. The inlet pressure of the data center cooling system can be greater than the outlet pressure of the data cooling system.

In an example, a method of sub-atmospheric direct liquid cooling can include receiving and storing, with an atmospheric reservoir, a cooling liquid from a cooling liquid source. Directing the cooling liquid from the atmospheric reservoir to an inlet of a data center cooling system. Receiving, with an inlet of a sub-atmospheric reservoir, the cooling liquid from an outlet of the data center cooling system. Controlling an inlet pressure at the inlet of the data center cooling system with a control valve. The control valve can be installed between the atmospheric reservoir and the inlet of the data center cooling system. Controlling an outlet pressure at the outlet of the data center cooling system with a pump. An inlet of the pump can be fluidically connected to an outlet of the sub-atmospheric reservoir. The inlet pressure of the data center cooling system can be greater than the outlet pressure of the data center cooling system.

### BRIEF DESCRIPTION OF THE DRAWINGS

Various examples are illustrated in the figures of the accompanying drawings. Such examples are demonstrative and not intended to be exhaustive or exclusive examples of the present subject matter.

FIG. 1 is a schematic of an example system that can include an example sub-atmospheric liquid supply system.

FIG. 2 is a schematic diagram of an example sub-atmospheric liquid supply system.

FIG. 3 is a schematic diagram of an example sub-atmospheric liquid supply system during an example of a standard operating mode.

FIG. 4 is a schematic diagram of an example sub-atmospheric liquid supply system during an example of a startup mode.

FIG. 5 is a schematic diagram of an example sub-atmospheric liquid supply system during an example of a shutdown mode.

FIG. 6 is a schematic diagram of an example sub-atmospheric liquid supply system during an example of an air purge mode.

FIG. 7 is a block diagram illustrating an example method of sub-atmospheric direct liquid cooling for a sub-atmospheric direct liquid cooling supply system.

### DETAILED DESCRIPTION

A sub-atmospheric liquid cooling system can be used to improve the cooling capacity of the cooling system and to mitigate risk to the data center or other system that requires a liquid from another source. The sub-atmospheric liquid cooling system, as disclosed herein, has many benefits over current liquid cooling systems. For example, the sub-atmospheric liquid cooling system described herein has sub-atmospheric liquid at and before the inlet of the data center cooling system, throughout the data center cooling system, and at the outlet or after the data center cooling system. Thus, if there were a leak, air would infiltrate the system instead of the liquid leaving the system and entering the data center, which can minimize clean-up after the leak compared to dielectric cooling systems. Additionally, because the sub-atmospheric liquid cooling system is below atmospheric pressure, the system can provide cooling liquid directly to the data center cooling system without using a heat exchanger between the systems. Water can be used in the sub-atmospheric liquid cooling system, which is non-toxic, inexpensive, and has better cooling capabilities than dielectric substances (which can be used in dielectric liquid cooling systems).

In an example, the sub-atmospheric liquid supply system can include an atmospheric reservoir fluidically connected to a working liquid source from which it can be configured to receive and store a working liquid at or above atmospheric pressure. The atmospheric reservoir can be fluidically connected to and configured to provide the working liquid to an inlet of a liquid system. A sub-atmospheric reservoir that can have an inlet fluidically connected to an outlet of the liquid system. A control valve can be fluidically connected between the atmospheric reservoir and the liquid system. The control valve can be configured to decrease a pressure of the working liquid below atmospheric pressure to control an inlet pressure at the inlet of the liquid system. A pump can be fluidically connected to an outlet of the sub-atmospheric reservoir. The pump can be configured to control an outlet pressure at the outlet of the liquid system. The inlet pressure of the liquid system can be greater than the outlet pressure of the liquid system.

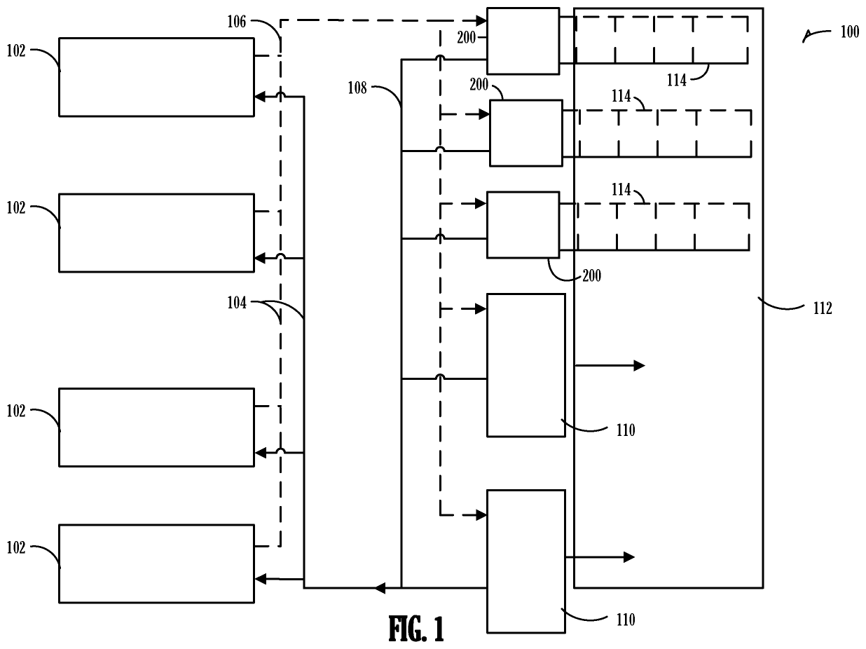

FIG. 1 is a schematic of an example liquid handling system 100 that can include an example sub-atmospheric liquid supply system 200. The liquid handling system can be a data center cooling system, hot water systems, brine systems, systems to circulate hazardous substances, such as, for example, hydrofluoric acid, any other system where a liquid is circulated in a region where leaks would result in issues for any equipment or personnel in the region, or the like.

As shown in FIG. 1, the liquid handling system 100 can include a working liquid source 102, the working liquid source 102 can be configured to provide a working liquid 104 to other components of the liquid handling system 100. In examples, the working liquid source 102 can be a single-phase liquid cooling unit, an air-cooled system, a two-phase liquid cooling unit, a heating source, any other system that conditions or prepares a liquid for use in the liquid handling system 100, or the like. In examples, the working liquid source 102 can include a heat exchanger that exchanges heat between a first working fluid of the working liquid source 102 and a second working fluid of the liquid handling system 100, or more specifically, the sub-atmospheric liquid supply system 200.

The working liquid 104 in the liquid handling system 100 can be water, glycol, dielectric fluid, refrigerant, nanofluids, liquid metals, any combination thereof, or the like. The working liquid 104 can be input working fluid 106 and output working fluid 108. The input working fluid 106 can be directed into other components of the liquid handling system 100. The output working fluid 108 can be received by the working liquid source 102 from other components of the liquid handling system 100. The working liquid source 102 can recycle the working liquid 104 such that the working liquid source 102 can process (e.g., heat, cool, pressurize, or the like) the output working fluid 108 to generate the input working fluid 106.

The liquid handling system 100 can include one or more fan coil walls (e.g., fan coil units, heat exchange devices, or fan coils), hereinafter referred to as “fan coil wall 110”. The fan coil wall 110 can be configured to provide air cooling within the liquid handling system 100. For example, the fan coil wall 110 can provide cooling to other components of the liquid handling system 100, such as, for example, a data hall 112. The fan coil wall 110 can work in concert with the sub-atmospheric liquid supply system 200 to provide heat transfer to one or more components of the liquid handling system 100, such as, for example, the data hall 112. As discussed herein, the liquid handling system 100 can be used for other uses, such as, for example, heating, cooling, or liquid transport. Thus, the fan coil wall 110 can be used to supply heated or cooled air to other components of the liquid handling system 100.

The data hall 112 can be a room that includes a plurality of servers, processors, controllers, or the like, hereinafter referred to as servers 114. The servers 114 can require cooling, which can be provided in concert by the fan coil wall 110 and the sub-atmospheric liquid supply system 200. The fan coil wall 110 and the sub-atmospheric liquid supply system 200 can work in concert to cool the data hall 112.

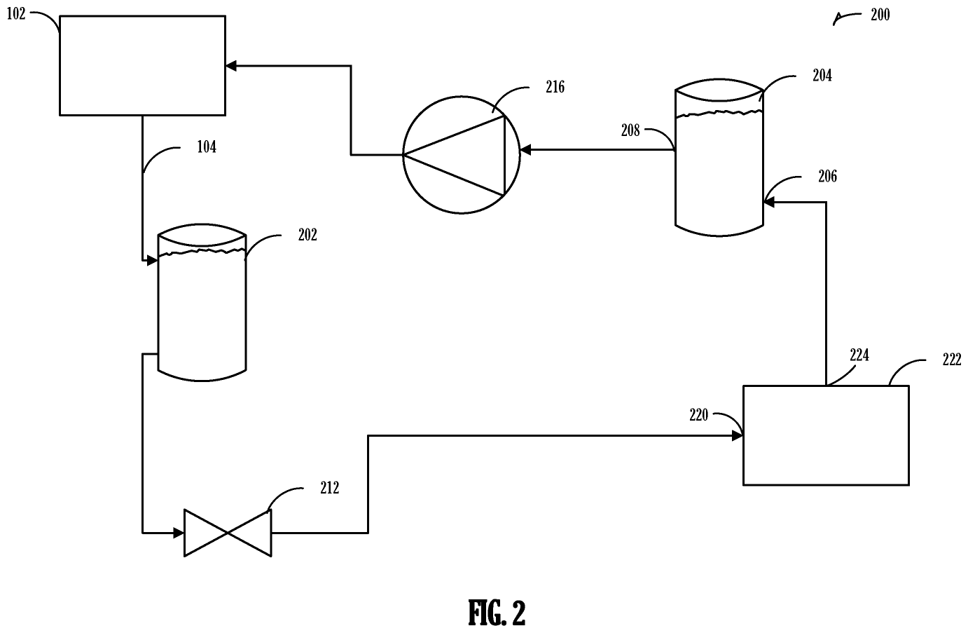

The above discussion is intended to provide an overview of the subject matter of the present patent application. It is not intended to provide an exclusive or exhaustive explanation of the disclosure. The description below provides further information about the present disclosure. The sub-atmospheric liquid supply system 200 will be discussed in more detail with reference to FIGS. 2-7.

FIG. 2 is a schematic diagram of an example sub-atmospheric liquid supply system 200. The sub-atmospheric liquid supply system 200 can include an atmospheric reservoir 202, a sub-atmospheric reservoir 204, a control valve 212, and a pump 216.

The atmospheric reservoir 202 can be a tank, vessel, or storage implement that can store the working liquid 104 and supply the working liquid 104 to other components of the liquid handling system 100. The atmospheric reservoir 202 can be fluidically connected to the working liquid source 102, from which the atmospheric reservoir 202 can be configured to receive and store a working liquid (e.g., the working liquid 104) at or above atmospheric pressure. The atmospheric reservoir 202 can be fluidically connected to and configured to provide the working liquid to an inlet 220 a liquid system 222 (e.g., the data hall 112 (FIG. 1)).

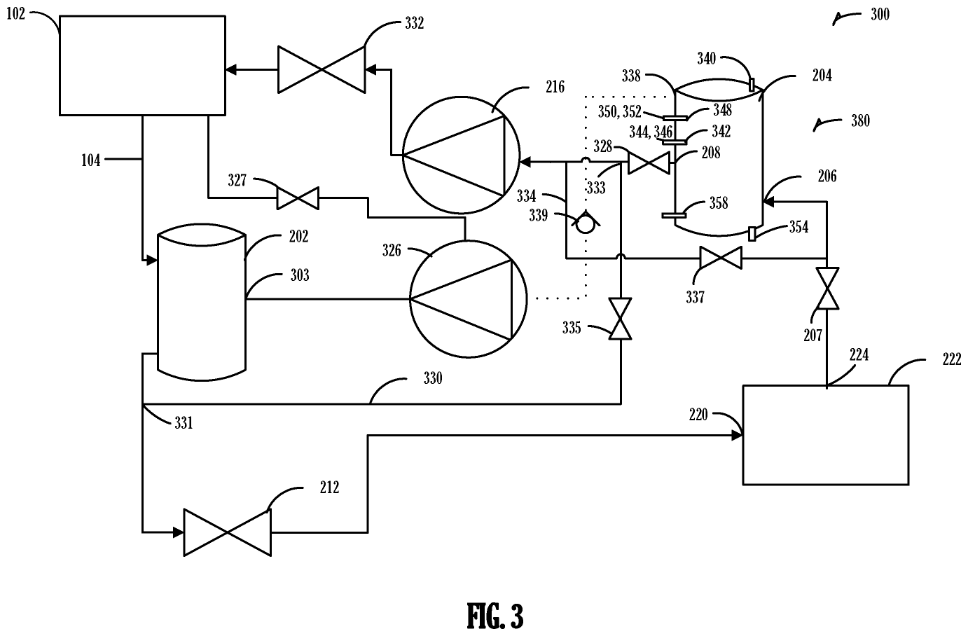

The sub-atmospheric reservoir 204 can be a tank, vessel, or storage implement that can store the working liquid 104 and supply the working liquid 104 to other components of the liquid handling system 100. The sub-atmospheric reservoir 204 can also be configured to separate the working liquid 104 from the air within the sub-atmospheric liquid supply system 200. The atmospheric reservoir 202 and the sub-atmospheric reservoir 204 are shown as separate tanks, which are isolated from one another. In an example, the atmospheric reservoir 202 and the sub-atmospheric reservoir 204 can be separate portions of the same tank, where each of the portions are isolated from one another. The sub-atmospheric reservoir 204 can include an inlet 206. The inlet 206 of the sub-atmospheric reservoir 204 can be fluidically connected to an outlet 224 of the liquid system 222. In examples, a valve 207 (first shown in FIG. 3) can be fluidically connected between the outlet 224 and the inlet 206 to control flow therebetween.

The control valve 212 can drop the working liquid 104 from the atmospheric reservoir 202 from super-atmospheric to sub-atmospheric. The control valve 212 can be fluidically connected between the atmospheric reservoir 202 and the liquid system 222. The control valve 212 can be configured to decrease the pressure of the working liquid 104 below atmospheric pressure to control an inlet pressure at the inlet 220 of the liquid system 222. For example, the control valve 212 can be configured to control the pressure of the working liquid 104 between the atmospheric reservoir 202 and the liquid system 222 between −1 kPa and −10 kPa. In another example, the control valve 212 can be configured to control the pressure of the working liquid 104 between the atmospheric reservoir 202 and the liquid system 222 between −1 kPa and −20 kPa. In yet another example, the control valve 212 can be configured to control the pressure of the working liquid 104 between the atmospheric reservoir 202 and the liquid system 222 between −1 kPa and −30 kPa. In another example, the control valve 212 can be configured to control the pressure of the working liquid 104 between the atmospheric reservoir 202 and the liquid system 222 between −1 kPa and −40 kPa.

The pump 216 can be a centrifugal pump, a positive displacement pump (e.g., a reciprocating pump, a submersible pump, rotary pumps, diaphragm pump, or the like). The pump 216 can be fluidically connected to an outlet 208 of the sub-atmospheric reservoir 204. As shown in FIG. 2, the pump 216 can be fluidically connected to the working liquid source 102 to return the working liquid 104 to the working liquid source 102. The pump 216 can be configured to control an outlet pressure at the outlet 224 of the liquid system 222. For example, the pump 216 can be configured to control the pressure of the working liquid 104 between the outlet 224 of the liquid system 222 and the pump 216 between −40 kPa and −50 kPa (e.g., the pump 216 can control the pump 216 to −40 kPa, −41 kPa, −42 kPa, . . . , or −50 kPa). In another example, the pump 216 can be configured to control the pressure of the working liquid 104 between the outlet 224 of the liquid system 222 and the pump 216 between −20 kPa and −80 kPa. In another example, the pump 216 can be configured to control the pressure of the working liquid 104 between the outlet 224 of the liquid system 222 and the pump 216 between −10 kPa and −75 kPa. Therefore, the inlet pressure at the inlet 220 of the liquid system 222 can be greater (i.e., less negative) than the outlet pressure at the outlet 224 of the liquid system 222, which can generate a pressure gradient to drive the working liquid 104 through the liquid system 222.

FIG. 3 is a schematic diagram of an example sub-atmospheric liquid supply system 300 during an example of a standard operating mode 301. The sub-atmospheric liquid supply system 300 (e.g., the sub-atmospheric liquid supply system 200) can be configured to transport a sub-atmospheric liquid (e.g., the working liquid 104) from a first system (e.g., the liquid handling system working liquid source 102) to a second system (e.g., the liquid system 222). The sub-atmospheric liquid supply system 300 can include a liquid ring pump 326, a return valve 328, a control valve bypass 330, a second control valve 332, and a sub-atmospheric reservoir bypass line 334. The sub-atmospheric reservoir 204 can include a suction vent 338, an air vent 340, a low-level switch 342, a top-level switch 348, and a drain 354. The low-level switch 342 can generate a low-level open signal 344 and a low-level closed signal 346. The top-level switch 348 can generate a top-level open signal 350 and a top-level closed signal 352.

The liquid ring pump 326 can be fluidically connected to the working liquid source 102, the suction vent 338 of the sub-atmospheric reservoir 204, and to a second inlet 303 of the atmospheric reservoir 202. A control valve 327 can control the working liquid 104 flow from the working liquid source 102. The liquid ring pump 326 can draw air from the suction vent 338 of the sub-atmospheric reservoir 204 to decrease pressure within the sub-atmospheric reservoir 204 and supply the working liquid 104 to the atmospheric reservoir 202. The suction vent 338 can include a check valve 339 that can prevent air from being introduced to the sub-atmospheric reservoir 204 via the suction vent 338.

The liquid ring pump 326 can decrease the amount of air in the sub-atmospheric liquid supply system 300 while adding more of the working liquid 104 into the sub-atmospheric liquid supply system 300. Therefore, the liquid ring pump 326 can decrease the pressure (i.e., make the pressure more negative) of the working liquid 104 within the sub-atmospheric reservoir 204. The liquid ring pump 326 can be controlled by the low-level switch 342 and the top-level switch 348, which will be discussed in more detail herein. In examples, the liquid ring pump 326 can be controlled by one or more pressure sensors throughout the sub-atmospheric liquid supply system 300. Here, the pressure sensor can detect a pressure of the water column within the tanks (e.g., the atmospheric reservoir 202 or the sub-atmospheric reservoir 204) to determine an amount of air to remove from the liquid within the tanks. In some examples, the liquid ring pump 326 can be controlled using multiple methods or techniques. For example, the liquid ring pump 326 can utilize a control valve on a pump suction or pump discharge side, speed control, or a combination of these two methods.

The sub-atmospheric liquid supply system 300 can include a cyclonic air separator. The cyclonic air separator can be used to remove gas from the gas from the sub-atmospheric liquid supply system. For example, the cyclonic air separator can be included in atmospheric reservoir 202, the sub-atmospheric reservoir 204, or any other component of the sub-atmospheric liquid supply system 300 to separate the air and liquid within the system and draw only the liquid without (or with minimal air) through the sub-atmospheric liquid supply system 300. In examples, multiple cyclonic air separators can be included to separate air and liquid in one or more locations throughout the sub-atmospheric liquid supply system 300.

The return valve 328 can be fluidically connected between the outlet 208 of the sub-atmospheric reservoir 204 and the pump 216. The return valve 328 can be operable to fluidically connect or fluidically isolate the sub-atmospheric reservoir 204 and the pump 216. The return valve 328 will be discussed in more detail herein.

The control valve bypass 330 can have an inlet 331 fluidically connected between the atmospheric reservoir 202 and the control valve 212 and an outlet 333 fluidically connected between the return valve 328 and the pump 216. The control valve bypass 330 can include one or more variable flow valves (e.g., a flow valve 335) that can be modulated to open and close to control the flow of the working liquid 104 therethrough the control valve bypass 330. The control valve bypass 330 will be discussed in more detail herein.

The second control valve 332 can be fluidically connected between the pump 216 and the working liquid source 102. The second control valve 332 can control the pressure of the working liquid 104 as the working liquid 104 leaves the sub-atmospheric liquid supply system 200 (FIG. 2) and returns to the working liquid source 102. Thus, the second control valve 332 can be controlled to a pressure complementary to the working liquid source 102 to prevent any pressure surges or potential damage to the working liquid source 102.

The sub-atmospheric reservoir bypass line 334 can be fluidically connected between the outlet 224 of the liquid system 222 and the inlet 206 of the sub-atmospheric reservoir 204 and to the pump 216. Thus, the sub-atmospheric reservoir bypass line 334 can direct the working liquid 104 from the liquid system 222 to the pump 216 bypassing the sub-atmospheric reservoir 204. The sub-atmospheric reservoir bypass line 334 can include one or more variable flow valves (e.g., a valve 337) that can be modulated to open and close to control the flow of the working liquid 104 therethrough the sub-atmospheric reservoir bypass line 334. The sub-atmospheric reservoir bypass line 334 will be discussed in more detail herein.

As discussed herein, the suction vent 338 and the air vent 340 can be configured to draw air out of the sub-atmospheric liquid supply system 300 and to introduce air into the sub-atmospheric liquid supply system 300, respectively. As shown in FIG. 3, the suction vent 338 can be located near a top of the sub-atmospheric reservoir 204 because air will have a lower density than the working liquid 104, which will cause the air introduced to the sub-atmospheric liquid supply system 300 to collect at the top of the sub-atmospheric reservoir 204. The suction vent 338 can be fluidically connected to the liquid ring pump 326 to remove the collected air from the sub-atmospheric reservoir 204 and decrease pressure in the sub-atmospheric reservoir 204. The air vent 340 can be opened to introduce air into the sub-atmospheric liquid supply system 300 and increase a pressure of the sub-atmospheric liquid supply system 300.

The low-level switch 342 can be installed in the sub-atmospheric reservoir 204 at a pre-determined low level. In another example, the low-level switch 342 can be installed within the sub-atmospheric reservoir 204 and be configured to detect when the working liquid 104 within the sub-atmospheric reservoir 204 has reached the pre-determined low level. In another example, the low-level switch 342 can be installed outside the sub-atmospheric reservoir 204 but configured to detect a pre-determined low level of the working liquid 104 within the sub-atmospheric reservoir 204. The low-level switch 342 can be configured to generate a low-level open signal 344 and a low-level closed signal 346. The low-level open signal 344 can indicate that the working liquid 104 within the sub-atmospheric reservoir 204 is below the pre-determined low level. The low-level closed signal 346 can indicate that the working liquid 104 within the sub-atmospheric reservoir 204 is at or above the pre-determined low level.

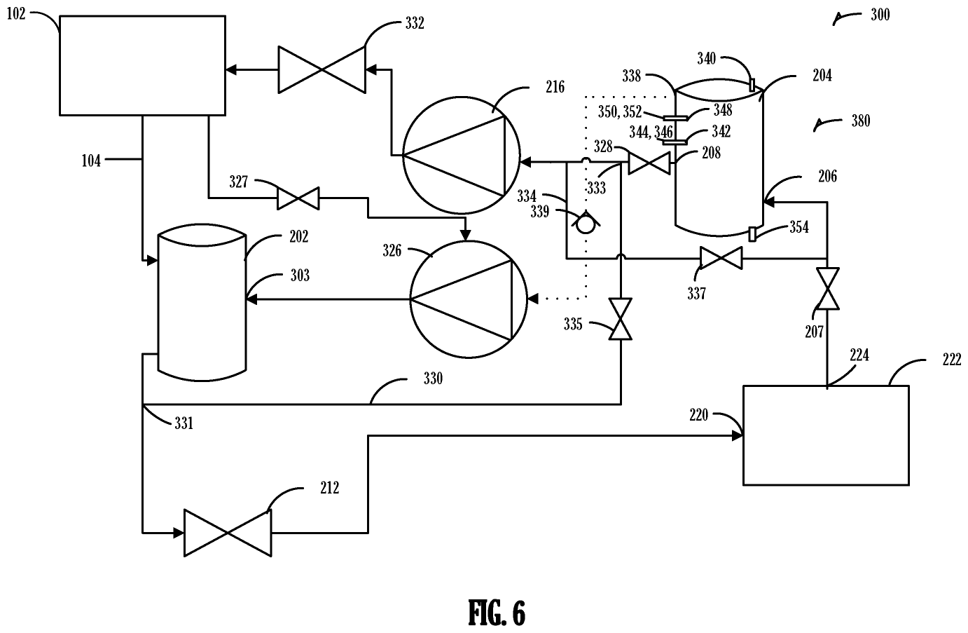

The top-level switch 348 can be installed in the sub-atmospheric reservoir 204 at a pre-determined top level, which is above the pre-determined low level of the low-level switch 342. In another example, the top-level switch 348 can be installed within the sub-atmospheric reservoir 204 and be configured to detect when the working liquid 104 within the sub-atmospheric reservoir 204 has reached the pre-determined top level. In another example, the top-level switch 348 can be installed outside the sub-atmospheric reservoir 204 but be configured to detect the pre-determined top level (higher than the pre-determined low level that the low-level switch 342 is configured to detect) of the working liquid 104 within the sub-atmospheric reservoir 204. The top-level open signal 350 can indicate that the working liquid 104 within the sub-atmospheric reservoir 204 is below the pre-determined top level. The top-level closed signal 352 can indicate that the working liquid 104 within the sub-atmospheric reservoir 204 is at or above the pre-determined top level. The liquid ring pump 326, the low-level switch 342, and the top-level switch 348 will be discussed in more detail with reference to FIG. 6.

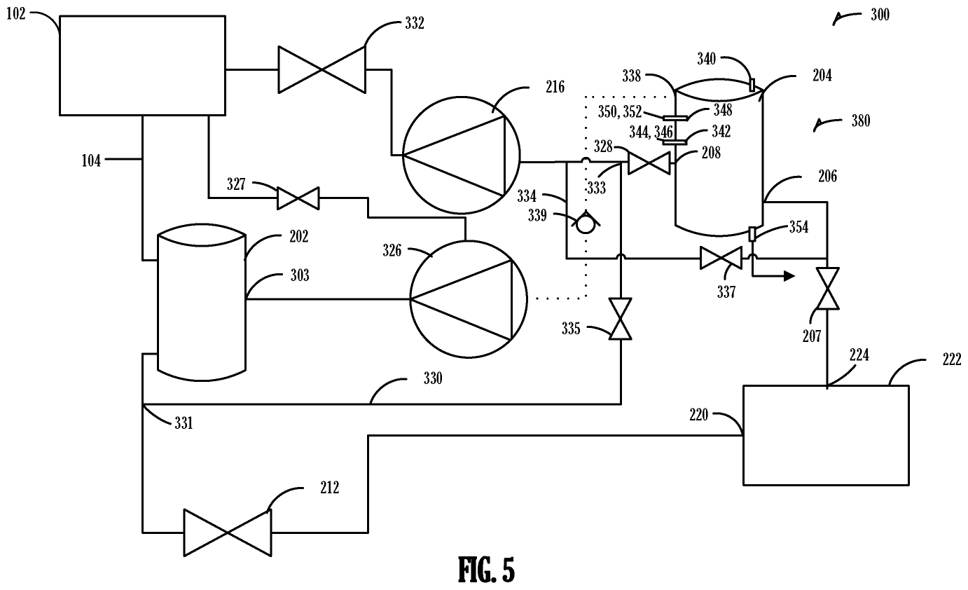

The drain 354 can be configured to be open upon shutdown of the sub-atmospheric liquid supply system 300 to drain the working liquid 104 within the sub-atmospheric reservoir 204 and permit the sub-atmospheric reservoir 204 and the liquid system 222 to reach atmospheric pressure. The drain 354 will be discussed in more detail with reference to FIG. 5.

As shown in FIG. 3, the sub-atmospheric liquid supply system 300 is in the standard operating mode 301. In the standard operating mode 301, the control valve 212 is in auto mode and controlling pressure to a setpoint pressure level, the drain 354 is closed, the control valve bypass 330 can be closed, the suction vent 338 and the air vent 340 can be closed, the return valve 328 can be fully open, the second control valve 332 can be in auto mode and controlling to a setpoint pressure level, the pump 216 can be in auto mode and controlling to a pre-determined threshold pressure, and the liquid ring pump 326 can be off and ready to start if commanded by the low-level switch 342 or the top-level switch 348.

The sub-atmospheric liquid supply system 300 can also include a pressure sensor 358. The pressure sensor 358 can be in communication with the sub-atmospheric reservoir 204 to determine pressure therewithin the sub-atmospheric reservoir 204. Thus, the liquid ring pump 326 can be operated using the pressures detected within the sub-atmospheric reservoir 204 by the pressure sensor 358 instead of using the low-level switch 342 and the top-level switch 348. In examples, the pressure sensor 358 can be used in addition to the low-level switch 342 and the top-level switch 348 to control the liquid ring pump 326.

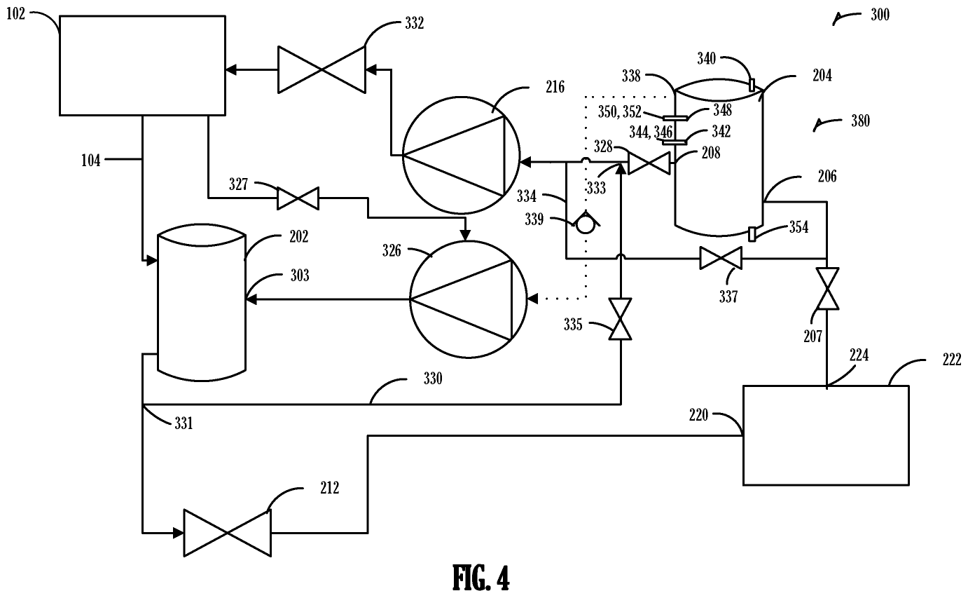

In addition to the standard operating mode 301, the sub-atmospheric liquid supply system 300 can include a startup mode 360 (shown in FIG. 4), a shutdown mode 370 (shown in FIG. 5), and an air purge mode 380 (shown in FIG. 6).

FIG. 4 is a schematic diagram of an example sub-atmospheric liquid supply system 300 during an example of the startup mode 360. During the startup mode 360, the control valve bypass 330 can be opened, the second control valve 332 can be at least partially opened, the pump 216 can be turned on, the control valve 212 can be set to an auto control mode to control the inlet pressure at the inlet 220 of the liquid system 222 to a pre-determined value, and the liquid ring pump 326 can be turned on to decrease pressure throughout the sub-atmospheric reservoir 204 and the liquid system 300.

From the state of the sub-atmospheric liquid supply system 300 shown in FIG. 4, the startup mode 360 can also continue with the return valve 328 opening once the low-level closed signal 346 is received. Once the return valve 328 is fully open, the control valve bypass 330 can be closed to stop the working liquid 104 from flowing within the control valve bypass 330 and direct the working liquid 104 into the liquid system 222. As the working liquid 104 flows into the liquid system 222, the sub-atmospheric liquid supply system 300 can enter the standard operating mode 301, which is shown in FIG. 3.

FIG. 5 is a schematic diagram of an example sub-atmospheric liquid supply system 300 during an example of a shutdown mode 370. To move from the standard operating mode 301 and into the shutdown mode 370, the liquid ring pump 326 can be turned off, and the vent 340 in the sub-atmospheric reservoir 204 can be opened to permit air into the sub-atmospheric reservoir 204, the sub-atmospheric reservoir bypass line 334 can be opened, the control valve bypass 330 can be opened, and the control valve 212 can be turned off.

After the sub-atmospheric reservoir 204 is mostly drained of the working liquid 104, the sub-atmospheric reservoir bypass line 334, the return valve 328, and the air vent 340 can be closed, the pump 216 can be stopped, and the control valve bypass 330 can be closed. The drain 354 can be opened upon shutdown of the sub-atmospheric liquid supply system 300 to drain the working liquid 104 within the sub-atmospheric reservoir 204. The drain 354 can also increase the sub-atmospheric reservoir 204 and the liquid system 300 to atmospheric pressure.

FIG. 6 is a schematic diagram of an example sub-atmospheric liquid supply system 300 during an example of an air purge mode 380. As discussed herein, the liquid ring pump 326 is fluidically connected to the sub-atmospheric reservoir 204 via the suction vent 338 such that the liquid ring pump 326 can draw air out of the sub-atmospheric reservoir 204 to decrease pressure within the sub-atmospheric reservoir 204 and the sub-atmospheric liquid supply system 300. As the liquid ring pump 326 draws air out of the sub-atmospheric reservoir 204 the liquid ring pump 326 can pump working liquid 104 from the working liquid source 102 into the atmospheric reservoir 202 using the air as an energy source for the liquid ring pump 326.

As discussed herein, the low-level switch 342 and the top-level switch 348 can control the liquid ring pump 326. For example, as the liquid ring pump 326 is in auto control mode, the liquid ring pump 326 can turn on upon receiving a top-level open signal 350 and turn off upon receiving a top-level closed signal 352. The liquid ring pump 326 can also be turned on upon receiving a low-level closed signal 346 during the startup mode 360, which can help depressurize the sub-atmospheric reservoir 204 and remove air from the sub-atmospheric reservoir 204.

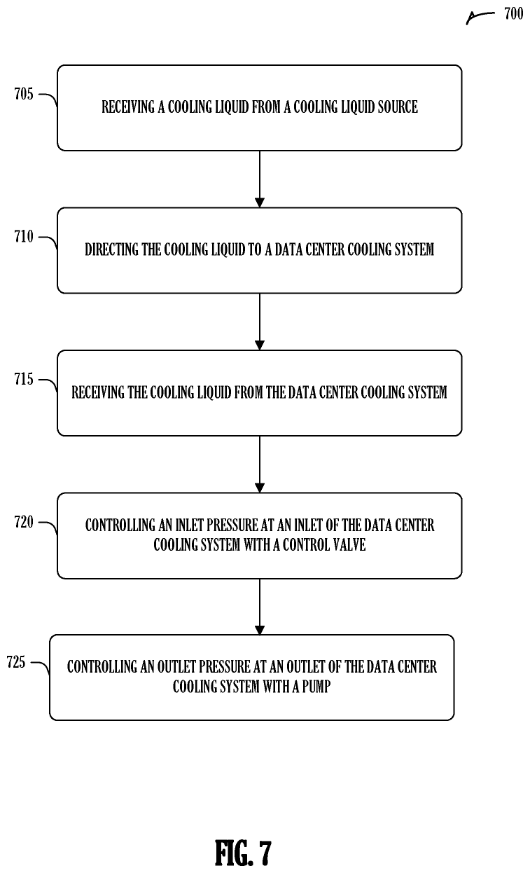

FIG. 7 illustrates a schematic view of the method 700, in accordance with at least one example of this disclosure. The method 700 can be a method of sub-atmospheric direct liquid cooling for a sub-atmospheric direct liquid cooling supply system. The method can include operations 705-725.

At operation 705, the method 700 can include receiving a cooling liquid from a cooling liquid source. For example, the method 700 can include receiving a working liquid 104 (first shown in FIG. 1) from the working liquid source 102 (first shown in FIG. 1) with the atmospheric reservoir 202 (first shown in FIG. 2). The atmospheric reservoir 202 can receive and store a buffer of the working liquid 104 for the system (e.g., the liquid handling system 100, the sub-atmospheric liquid supply system 200, or the sub-atmospheric liquid supply system 300). The buffer can help the systems continue to run after a shutdown of the working liquid source 102.

At operation 710, the method 700 can include directing the cooling liquid to a data center cooling system. For example, the method 700 can include directing the working liquid 104 (FIG. 1) from the atmospheric reservoir 202 (FIG. 2) to the inlet 220 of the liquid system 222 (both in FIG. 2).

At operation 715, the method 700 can include receiving the cooling fluid from the data center cooling system. For example, the method 700 can include receiving, with the inlet 206 of the sub-atmospheric reservoir 204 (both in FIG. 2), the working liquid 104 from the outlet 224 of the liquid system 222 (both in FIG. 2).

At operation 720, the method 700 can include controlling an inlet pressure at an inilet of the data center cooling system with a control valve. For example, the method 700 can include controlling an inlet pressure at the inlet 220 of the liquid system 222 with the control valve 212 (shown in FIG. 2).

At operation 725, the method 700 can include controlling an outlet pressure at an outlet of the data center cooling system with a pump. For example, the method 700 can include controlling an outlet pressure at the outlet 224 of the liquid system 222 with the pump 216 (all shown in FIG. 2). In examples, the liquid ring pump 326 (FIG. 3) can decrease the pressure within the sub-atmospheric reservoir 204 (FIG. 2) by drawing air out of the sub-atmospheric reservoir via the suction vent 338 (FIG. 3).

The method 700 can also include monitoring, with a top-level liquid switch 348, a liquid level (e.g., level of the working liquid 104 (FIG. 1)) within the sub-atmospheric reservoir 204 (FIG. 2). The top-level liquid switch 348 can be configured to generate the top-level open signal 350 and the top-level closed signal 352. The top-level open signal 350 can indicate that the cooling liquid (e.g., the working liquid 104) within the sub-atmospheric reservoir 204 is below a pre-determined maximum level. The top-level closed 352 signal can indicate that the cooling liquid within the sub-atmospheric reservoir 204 is at or above the pre-determined maximum level.

The method 700 can also include monitoring, with a low-level liquid switch 342, a liquid (e.g., the working liquid 104) level within the sub-atmospheric reservoir 204. The low-level liquid switch 342 can be configured to generate a low-level open signal 344 and a low-level closed signal 346. The low-level open signal 344 can indicate that the cooling liquid within the sub-atmospheric reservoir 204 is below a pre-determined minimum level. The low-level closed signal 346 can indicate that the cooling liquid within the sub-atmospheric reservoir 204 is at or above the pre-determined minimum level.

As discussed herein, the low-level switch 342 and the top-level switch 348 can be used to control the liquid ring pump 326 to purge air out of the system (e.g., the liquid handling system 100, the sub-atmospheric liquid supply system 200, or the sub-atmospheric liquid supply system 300). As discussed herein, the pressure at the inlet 220 of the liquid system 222 can be greater (i.e., less negative) than the pressure at the outlet 224 of the liquid system 222.

As discussed herein with reference to FIGS. 3, 4, and 5, the sub-atmospheric direct liquid cooling supply system comprises a startup mode (e.g., the startup mode 360 shown in FIG. 4), a standard operating mode (e.g., the standard operating mode 301 shown in FIG. 3), and a shutdown mode (e.g., the shutdown mode 370 shown in FIG. 5). The start-up mode can include opening a control valve bypass (e.g., the control valve bypass 330 (FIG. 3). The control valve bypass can have an inlet fluidically connected between the atmospheric reservoir (e.g., the atmospheric reservoir 202 (FIG. 2) and the control valve (e.g., the control valve 212 (FIG. 2) and an outlet fluidically connected between the sub-atmospheric reservoir (e.g., the sub-atmospheric reservoir 204 (FIG. 2)) and the pump (e.g., the pump 216 (FIG. 2)). The startup mode can also include opening, at least partially, a second control valve (e.g., second control valve 332 (FIG. 3)), the second control valve can be fluidically connected between the pump and the cooling liquid source and the atmospheric reservoir, powering on the pump, setting the control valve to an auto control mode to control the inlet pressure at the inlet of the data center cooling system to a pre-determined value, and powering on the liquid ring pump to decrease pressure throughout the sub-atmospheric reservoir and the data center cooling system.

The startup mode can also include receiving the low-level closed signal, opening a return valve (e.g., the return valve 328 (FIG. 3)) upon receiving the low-level closed signal. The return valve can be fluidically connected between the outlet of the sub-atmospheric reservoir and the pump and configured to fluidically connect or fluidically isolate the sub-atmospheric reservoir and the pump. The startup mode can also include closing the control valve bypass, on condition that the return valve is fully open, to stop flow of the cooling liquid within the control valve bypass and direct working fluid into the data center cooling system.

The shutdown mode can include powering off the liquid ring pump, opening a vent (e.g., the air vent 340 (FIG. 3)) in the sub-atmospheric reservoir to permit air into the sub-atmospheric reservoir and opening a sub-atmospheric reservoir bypass line (e.g., the sub-atmospheric reservoir bypass line 334 (FIG. 3)). The sub-atmospheric reservoir bypass line can be fluidically connected between the outlet of the data center cooling system and the inlet of the sub-atmospheric reservoir and to the pump and configured to direct cooling liquid from the data center cooling system to the pump bypassing the sub-atmospheric reservoir. The shutdown mode can also include opening a control valve bypass (e.g., the control valve bypass 330 (FIG. 3)). The control valve bypass can have an inlet fluidically connected between the atmospheric reservoir and the control valve and an outlet fluidically connected between the sub-atmospheric reservoir and the pump. The shutdown method can also include turning off the control valve.

The shutdown mode can also include opening a drain (e.g., the drain 354 (FIG. 3)) of the sub-atmospheric reservoir, on condition that the sub-atmospheric direct liquid cooling supply system is shut down, to drain liquid within the sub-atmospheric reservoir and permit the sub-atmospheric reservoir and the data center cooling system to reach atmospheric pressure.

The following, non-limiting examples, detail certain aspects of the present subject matter to solve the challenges and provide the benefits discussed herein, among others.

Example 1 is a sub-atmospheric liquid supply system that can inlcude an atmospheric reservoir fluidically connected to a working liquid source from which it can be configured to receive and store a working liquid at or above atmospheric pressure, the atmospheric reservoir can be fluidically connected to and configured to provide the working liquid to an inlet of a liquid system; a sub-atmospheric reservoir can have an inlet fluidically connected to an outlet of the liquid system; a control valve can be fluidically connected between the atmospheric reservoir and the liquid system, the control valve can be configured to decrease a pressure of the working liquid below atmospheric pressure to control an inlet pressure at the inlet of the liquid system; and a pump can be fluidically connected to an outlet of the sub-atmospheric reservoir, the pump can be configured to control an outlet pressure at the outlet of the liquid system, the inlet pressure of the liquid system can be greater than the outlet pressure of the liquid system.

In Example 2, the subject matter of Example 1 can include, wherein the sub-atmospheric reservoir comprises an air vent, the air vent configured to draw air out of the sub-atmospheric liquid supply system and to decrease pressure in the sub-atmospheric reservoir.

In Example 3, the subject matter of Example 2 can include, a liquid ring pump fluidically connected to the working liquid source, the air vent of the sub-atmospheric reservoir, and to a second inlet of the atmospheric reservoir, the liquid ring pump configured to draw air from the air vent of the sub-atmospheric reservoir to decrease pressure in the sub-atmospheric reservoir and to supply working liquid to the atmospheric reservoir.

In Example 4, the subject matter of Example 3 can include, wherein the sub-atmospheric reservoir comprises: a low-level liquid switch configured to generate a low-level open signal and a low-level closed signal, the low-level open signal indicative of the working liquid within the sub-atmospheric reservoir is below a pre-determined minimum level, the low-level closed signal indicative of the working liquid within the sub-atmospheric reservoir being at or above the pre-determined minimum level; and a top-level liquid switch configured to generate a top-level open signal and a top-level closed signal, the top-level open signal indicative of the working liquid within the sub-atmospheric reservoir being below a pre-determined maximum level, the top-level closed signal indicative of the working liquid within the sub-atmospheric reservoir being at or above the pre-determined maximum level.

In Example 5, the subject matter of Example 4 can include, a return valve fluidically connected between the outlet of the sub-atmospheric reservoir and the pump, the return valve being configured to fluidically connect or fluidically isolate the sub-atmospheric reservoir and the pump.

In Example 6, the subject matter of Example 5 can include, a control valve bypass having an inlet fluidically connected between the atmospheric reservoir and the control valve and an outlet fluidically connected between the sub-atmospheric reservoir and the pump; and a second control valve fluidically connected between the pump and the working liquid source and the atmospheric reservoir.

In Example 7, the subject matter of Example 6 can include, wherein the sub-atmospheric liquid supply system comprises a startup mode, a standard operating mode, and a shutdown mode.

In Example 8, the subject matter of Example 7 can include, wherein during the startup mode, the control valve bypass is opened, the second control valve is at least partially opened, the pump is turned on, the control valve is set to an auto control mode to control the inlet pressure at the inlet of the liquid system to a pre-determined value, and the liquid ring pump is turned on to decrease pressure throughout the sub-atmospheric reservoir and the liquid system.

In Example 9, the subject matter of Example 8 can include, wherein during the startup mode, the return valve begins to open once the low-level closed signal is received, and wherein once the return valve is fully open, the control valve bypass closes to stop liquid flow within the control valve bypass and to direct working fluid into the liquid system.

In Example 10, the subject matter of Example 9 can include, wherein the liquid ring pump is in auto control mode such that the liquid ring pump turns on upon receiving a top-level open signal and turns off upon receiving a top-level closed signal.

In Example 11, the subject matter of Examples 7-10 can include, a sub-atmospheric reservoir bypass line fluidically connected between the outlet of the liquid system and the inlet of the sub-atmospheric reservoir and to the pump, the sub-atmospheric reservoir bypass line configured to direct working liquid from the liquid system to the pump bypassing the sub-atmospheric reservoir.

In Example 12, the subject matter of Example 11 can include, wherein in the shutdown mode, the liquid ring pump is turned off, and a vent in the sub-atmospheric reservoir is opened to permit air into the sub-atmospheric reservoir, the sub-atmospheric reservoir bypass line is opened, the control valve bypass is opened, and the control valve is turned off.

In Example 13, the subject matter of Example 12 can include, wherein once the sub-atmospheric reservoir is mostly drained of liquid, the sub-atmospheric reservoir bypass line, the return valve, and the air vent are closed, the pump is stopped, and the control valve bypass is closed.

In Example 14, the subject matter of Example 13 can include, a drain configured to be open upon shutdown of the sub-atmospheric liquid supply system to drain liquid within the sub-atmospheric reservoir and permit the sub-atmospheric reservoir and the liquid system to reach atmospheric pressure.

Example 15 is a sub-atmospheric direct liquid cooling supply system comprising: an atmospheric reservoir fluidically connected to a cooling source from which it is configured to receive and store a cooling liquid at or above atmospheric pressure, the atmospheric reservoir fluidically connected to and configured to provide cooling liquid to an inlet of a data center cooling system; a sub-atmospheric reservoir having an inlet fluidically connected to an outlet of the data center cooling system; a control valve fluidically connected between the atmospheric reservoir and the data center cooling system, the control valve configured to decrease a pressure of the cooling liquid below atmospheric pressure to control an inlet pressure at the inlet of the data center cooling system; and a pump fluidically connected to an outlet of the sub-atmospheric reservoir, the pump configured to control an outlet pressure at an outlet of the data center cooling system, the inlet pressure of the data center cooling system being greater than the outlet pressure of the data center cooling system.

In Example 16, the subject matter of Example 15 can include, wherein the sub-atmospheric reservoir comprises an air vent, the air vent configured to draw air out of the sub-atmospheric direct liquid cooling supply system and to decrease pressure in the sub-atmospheric reservoir.

In Example 17, the subject matter of Example 16 can include, a liquid ring pump fluidically connected to the cooling source, the air vent of the sub-atmospheric reservoir, and to a second inlet of the atmospheric reservoir, the liquid ring pump configured to draw air from the air vent of the sub-atmospheric reservoir to decrease pressure in the sub-atmospheric reservoir and to supply cooling liquid to the atmospheric reservoir.

In Example 18, the subject matter of Example 17 can include, wherein the sub-atmospheric reservoir comprises: a low-level liquid switch configured to generate a low-level open signal and a low-level closed signal, the low-level open signal indicative of the cooling liquid within the sub-atmospheric reservoir is below a pre-determined minimum level, the low-level closed signal indicative of the cooling liquid within the sub-atmospheric reservoir being at or above the pre-determined minimum level; and a top-level liquid switch configured to generate a top-level open signal and a top-level closed signal, the top-level open signal indicative of the cooling liquid within the sub-atmospheric reservoir being below a pre-determined maximum level, the top-level closed signal indicative of the cooling liquid within the sub-atmospheric reservoir being at or above the pre-determined maximum level.

In Example 19, the subject matter of Example 18 can include, a return valve fluidically connected between the outlet of the sub-atmospheric reservoir and the pump, the return valve being configured to fluidically connect or fluidically isolate the sub-atmospheric reservoir and the pump.

In Example 20, the subject matter of Example 19 can include, a control valve bypass having an inlet fluidically connected between the atmospheric reservoir and the control valve and an outlet fluidically connected between the sub-atmospheric reservoir and the pump; and a second control valve fluidically connected between the pump and the cooling source and the atmospheric reservoir.

In Example 21, the subject matter of Example 20 can include, wherein the sub-atmospheric direct liquid cooling supply system comprises a startup mode, a standard operating mode, and a shutdown mode.

In Example 22, the subject matter of Example 21 can include, wherein during the startup mode, the control valve bypass is opened, the second control valve is at least partially opened, the pump is turned on, the control valve is set to an auto control mode to control the inlet pressure at the inlet of the data center cooling system to a pre-determined value, and the liquid ring pump is turned on to decrease pressure throughout the sub-atmospheric reservoir and the data center cooling system.

In Example 23, the subject matter of Example 22 can include, wherein during the startup mode, the return valve begins to open once the low-level closed signal is received, and wherein once the return valve is fully open, the control valve bypass closes to stop liquid flow within the control valve bypass and to direct working fluid into the data center cooling system.

In Example 24, the subject matter of Example 23 can include, wherein the liquid ring pump is in auto control mode such that the liquid ring pump turns on upon receiving a top-level open signal and turns off upon receiving a top-level closed signal.

In Example 25, the subject matter of Examples 21-24 can include, a sub-atmospheric reservoir bypass line fluidically connected between the outlet of the data center cooling system and the inlet of the sub-atmospheric reservoir and to the pump, the sub-atmospheric reservoir bypass line configured to direct cooling liquid from the data center cooling system to the pump bypassing the sub-atmospheric reservoir.

In Example 26, the subject matter of Example 25 can include, wherein in the shutdown mode, the liquid ring pump is turned off, and a vent in the sub-atmospheric reservoir is opened to permit air into the sub-atmospheric reservoir, the sub-atmospheric reservoir bypass line is opened, the control valve bypass is opened, and the control valve is turned off.

In Example 27, the subject matter of Example 26 can include, wherein once the sub-atmospheric reservoir is mostly drained of liquid, the sub-atmospheric reservoir bypass line, the return valve, and the air vent are closed, the pump is stopped, and the control valve bypass is closed.

In Example 28, the subject matter of Example 27 can include, a drain configured to be open upon shutdown of the sub-atmospheric direct liquid cooling supply system to drain liquid within the sub-atmospheric reservoir and permit the sub-atmospheric reservoir and the data center cooling system to reach atmospheric pressure.

Example 29 is a method of sub-atmospheric direct liquid cooling for a sub-atmospheric direct liquid cooling supply system, the method can include: receiving and storing, with an atmospheric reservoir, a cooling liquid from a cooling liquid source; directing the cooling liquid from the atmospheric reservoir to an inlet of a data center cooling system; receiving, with an inlet of a sub-atmospheric reservoir, the cooling liquid from an outlet of the data center cooling system; controlling an inlet pressure at the inlet of the data center cooling system with a control valve, the control valve installed between the atmospheric reservoir and the inlet of the data center cooling system; and controlling an outlet pressure at the outlet of the data center cooling system with a pump, an inlet of the pump fluidically connected to an outlet of the sub-atmospheric reservoir, the inlet pressure of the data center cooling system being greater than the outlet pressure of the data center cooling system.

In Example 30, the subject matter of Example 29 can include, wherein controlling the outlet pressure at the outlet of the data center cooling system further comprises: decreasing a pressure of the sub-atmospheric reservoir via a liquid ring pump fluidically connected to an air vent of the sub-atmospheric reservoir to draw air out of the sub-atmospheric reservoir.

In Example 31, the subject matter of Example 30 can include, wherein controlling the outlet pressure at the outlet of the data center cooling system further comprises: monitoring, with a top-level liquid switch, a liquid level within the sub-atmospheric reservoir, the top-level liquid switch configured to generate a top-level open signal and a top-level closed signal, the top-level open signal indicative of the cooling liquid within the sub-atmospheric reservoir being below a pre-determined maximum level, the top-level closed signal indicative of the cooling liquid within the sub-atmospheric reservoir being at or above the pre-determined maximum level; and monitoring, with a low-level liquid switch, a liquid level within the sub-atmospheric reservoir, the low-level liquid switch configured to generate a low-level open signal and a low-level closed signal, the low-level open signal indicative of the cooling liquid within the sub-atmospheric reservoir is below a pre-determined minimum level, the low-level closed signal indicative of the cooling liquid within the sub-atmospheric reservoir being at or above the pre-determined minimum level.

In Example 32, the subject matter of Example 31 can include, wherein the sub-atmospheric direct liquid cooling supply system comprises a startup mode, a standard operating mode, and a shutdown mode.

In Example 33, the subject matter of Example 32 can include, wherein the startup mode comprises: opening a control valve bypass, the control valve bypass having an inlet fluidically connected between the atmospheric reservoir and the control valve and an outlet fluidically connected between the sub-atmospheric reservoir and the pump; opening, at least partially, a second control valve, the second control valve fluidically connected between the pump and the cooling liquid source and the atmospheric reservoir; powering on the pump; setting the control valve to an auto control mode to control the inlet pressure at the inlet of the data center cooling system to a pre-determined value; and powering on the liquid ring pump to decrease pressure throughout the sub-atmospheric reservoir and the data center cooling system.

In Example 34, the subject matter of Example 33 can include, wherein the startup mode can include: receiving the low-level closed signal; opening a return valve upon receiving the low-level closed signal, the return valve fluidically connected between the outlet of the sub-atmospheric reservoir and the pump and configured to fluidically connect or fluidically isolate the sub-atmospheric reservoir and the pump ; and closing the control valve bypass, on condition that the return valve is fully open, to stop flow of the cooling liquid within the control valve bypass and direct working fluid into the data center cooling system.

In Example 35, the subject matter of Examples 32-34 can include, wherein the shutdown mode comprises: powering off the liquid ring pump; opening a vent in the sub-atmospheric reservoir to permit air into the sub-atmospheric reservoir; opening a sub-atmospheric reservoir bypass line, the sub-atmospheric reservoir bypass line is fluidically connected between the outlet of the data center cooling system and the inlet of the sub-atmospheric reservoir and to the pump, the sub-atmospheric reservoir bypass line configured to direct cooling liquid from the data center cooling system to the pump bypassing the sub-atmospheric reservoir; opening a control valve bypass, the control valve bypass having an inlet fluidically connected between the atmospheric reservoir and the control valve and an outlet fluidically connected between the sub-atmospheric reservoir and the pump; and turning off the control valve.

In Example 36, the subject matter of Examples 32-35 can include, wherein the shutdown mode comprises: opening a drain of the sub-atmospheric reservoir, on condition that the sub-atmospheric direct liquid cooling supply system is shut down, to drain liquid within the sub-atmospheric reservoir and permit the sub-atmospheric reservoir and the data center cooling system to reach atmospheric pressure.

Example 37 is an apparatus comprising means to implement of any of Examples 1-36.

Example 38 is a system to implement of any of Examples 1-36.

Example 39 is a method to implement of any of Examples 1-36.

Example 40 is an apparatus, system, or method to implement any elements of any of Examples 1-36.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The term “about,” as used herein, means approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 10%. In one aspect, the term “about” means plus or minus 10% of the numerical value of the number with which it is being used. Therefore, about 50% means in the range of 45%-55%. Numerical ranges recited herein by endpoints include all numbers and fractions subsumed within that range (e.g. 1 to 5 includes 1, 1.5, 2, 2.75, 3, 3.90, 4, 4.24, and 5). Similarly, numerical ranges recited herein by endpoints include subranges subsumed within that range (e.g. 1 to 5 includes 1-1.5, 1.5-2, 2-2.75, 2.75-3, 3-3.90, 3.90-4, 4-4.24, 4.24-5, 2-5, 3-5, 1-4, and 2-4). It is also to be understood that all numbers and fractions thereof are presumed to be modified by the term “about.”

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the embodiments should be determined with reference to the appended claims, along with the full scope of equivalents to which such claims are entitled.

1. A sub-atmospheric liquid supply system comprising:
an atmospheric reservoir fluidically connected to a working liquid source from which it is configured to receive and store a working liquid at or above atmospheric pressure, the atmospheric reservoir fluidically connected to and configured to provide the working liquid to an inlet of a liquid system;
a sub-atmospheric reservoir having an inlet fluidically connected to an outlet of the liquid system;
a control valve fluidically connected between the atmospheric reservoir and the liquid system, the control valve being configured to decrease a pressure of the working liquid below atmospheric pressure to control an inlet pressure at the inlet of the liquid system; and
a pump fluidically connected to an outlet of the sub-atmospheric reservoir, the pump configured to control an outlet pressure at the outlet of the liquid system, the inlet pressure of the liquid system being greater than the outlet pressure of the liquid system.

2. The sub-atmospheric liquid supply system of claim 1, wherein the sub-atmospheric reservoir comprises an air vent, the air vent configured to draw air out of the sub-atmospheric liquid supply system and to decrease pressure in the sub-atmospheric reservoir.

3. The sub-atmospheric liquid supply system of claim 2, comprising:
a liquid ring pump fluidically connected to the working liquid source, the air vent of the sub-atmospheric reservoir, and to a second inlet of the atmospheric reservoir, the liquid ring pump configured to draw air from the air vent of the sub-atmospheric reservoir to decrease pressure in the sub-atmospheric reservoir and to supply working liquid to the atmospheric reservoir.

4. The sub-atmospheric liquid supply system of claim 3, wherein the sub-atmospheric reservoir comprises:
a low-level liquid switch configured to generate a low-level open signal and a low-level closed signal, the low-level open signal indicative of the working liquid within the sub-atmospheric reservoir is below a pre-determined minimum level, the low-level closed signal indicative of the working liquid within the sub-atmospheric reservoir being at or above the pre-determined minimum level; and
a top-level liquid switch configured to generate a top-level open signal and a top-level closed signal, the top-level open signal indicative of the working liquid within the sub-atmospheric reservoir being below a pre-determined maximum level, the top-level closed signal indicative of the working liquid within the sub-atmospheric reservoir being at or above the pre-determined maximum level.

5. The sub-atmospheric liquid supply system of claim 4, comprising:
a return valve fluidically connected between the outlet of the sub-atmospheric reservoir and the pump, the return valve being configured to fluidically connect or fluidically isolate the sub-atmospheric reservoir and the pump.

6. The sub-atmospheric liquid supply system of claim 5, comprising:
a control valve bypass having an inlet fluidically connected between the atmospheric reservoir and the control valve and an outlet fluidically connected between the sub-atmospheric reservoir and the pump; and
a second control valve fluidically connected between the pump and the working liquid source and the atmospheric reservoir.

7. The sub-atmospheric liquid supply system of claim 6, wherein the sub-atmospheric liquid supply system comprises a startup mode, a standard operating mode, and a shutdown mode.

8. The sub-atmospheric liquid supply system of claim 7, wherein during the startup mode, the control valve bypass is opened, the second control valve is at least partially opened, the pump is turned on, the control valve is set to an auto control mode to control the inlet pressure at the inlet of the liquid system to a pre-determined value, and the liquid ring pump is turned on to decrease pressure throughout the sub-atmospheric reservoir and the liquid system.

9. The sub-atmospheric liquid supply system of claim 8, wherein during the startup mode, the return valve begins to open once the low-level closed signal is received, and wherein once the return valve is fully open, the control valve bypass closes to stop liquid flow within the control valve bypass and to direct working fluid into the liquid system.

10. The sub-atmospheric liquid supply system of claim 9, wherein the liquid ring pump is in auto control mode such that the liquid ring pump turns on upon receiving a top-level open signal and turns off upon receiving a top-level closed signal.

11. The sub-atmospheric liquid supply system of claim 7, comprising:
a sub-atmospheric reservoir bypass line fluidically connected between the outlet of the liquid system and the inlet of the sub-atmospheric reservoir and to the pump, the sub-atmospheric reservoir bypass line configured to direct working liquid from the liquid system to the pump bypassing the sub-atmospheric reservoir.

12. The sub-atmospheric liquid supply system of claim 11, wherein in the shutdown mode, the liquid ring pump is turned off, and a vent in the sub-atmospheric reservoir is opened to permit air into the sub-atmospheric reservoir, the sub-atmospheric reservoir bypass line is opened, the control valve bypass is opened, and the control valve is turned off.

13. The sub-atmospheric liquid supply system of claim 12, wherein once the sub-atmospheric reservoir is mostly drained of liquid, the sub-atmospheric reservoir bypass line, the return valve, and the air vent are closed, the pump is stopped, and the control valve bypass is closed.

14. The sub-atmospheric liquid supply system of claim 13, comprising a drain configured to be open upon shutdown of the sub-atmospheric liquid supply system to drain liquid within the sub-atmospheric reservoir and permit the sub-atmospheric reservoir and the liquid system to reach atmospheric pressure.

15. A sub-atmospheric direct liquid cooling supply system comprising:
an atmospheric reservoir fluidically connected to a cooling source from which it is configured to receive and store a cooling liquid at or above atmospheric pressure, the atmospheric reservoir fluidically connected to and configured to provide cooling liquid to an inlet of a data center cooling system;
a sub-atmospheric reservoir having an inlet fluidically connected to an outlet of the data center cooling system;
a control valve fluidically connected between the atmospheric reservoir and the data center cooling system, the control valve configured to decrease a pressure of the cooling liquid below atmospheric pressure to control an inlet pressure at the inlet of the data center cooling system; and
a pump fluidically connected to an outlet of the sub-atmospheric reservoir, the pump configured to control an outlet pressure at an outlet of the data center cooling system, the inlet pressure of the data center cooling system being greater than the outlet pressure of the data center cooling system.

16. The sub-atmospheric direct liquid cooling supply system of claim 15, wherein the sub-atmospheric reservoir comprises an air vent, the air vent configured to draw air out of the sub-atmospheric direct liquid cooling supply system and to decrease pressure in the sub-atmospheric reservoir.

17. The sub-atmospheric direct liquid cooling supply system of claim 16, comprising:
a liquid ring pump fluidically connected to the cooling source, the air vent of the sub-atmospheric reservoir, and to a second inlet of the atmospheric reservoir, the liquid ring pump configured to draw air from the air vent of the sub-atmospheric reservoir to decrease pressure in the sub-atmospheric reservoir and to supply cooling liquid to the atmospheric reservoir.

18. The sub-atmospheric direct liquid cooling supply system of claim 17, wherein the sub-atmospheric reservoir comprises:
a pressure sensor in communication with the sub-atmospheric reservoir, the pressure sensor configured to detect a pressure within the sub-atmospheric reservoir.

19. The sub-atmospheric direct liquid cooling supply system of claim 18, comprising:
a return valve fluidically connected between the outlet of the sub-atmospheric reservoir and the pump, the return valve being configured to fluidically connect or fluidically isolate the sub-atmospheric reservoir and the pump.

20. The sub-atmospheric direct liquid cooling supply system of claim 19, comprising:
a control valve bypass having an inlet fluidically connected between the atmospheric reservoir and the control valve and an outlet fluidically connected between the return valve and the pump; and
a second control valve fluidically connected between the pump and the cooling source and the atmospheric reservoir.

21. The sub-atmospheric direct liquid cooling supply system of claim 20, wherein the sub-atmospheric direct liquid cooling supply system comprises a startup mode, a standard operating mode, and a shutdown mode.

22. The sub-atmospheric direct liquid cooling supply system of claim 21, wherein during the startup mode, the control valve bypass is opened, the second control valve is at least partially opened, the pump is turned on, the control valve is set to an auto control mode to control the inlet pressure at the inlet of the data center cooling system to a pre-determined value, and the liquid ring pump is turned on to decrease pressure throughout the sub-atmospheric reservoir and the data center cooling system.

23. The sub-atmospheric direct liquid cooling supply system of claim 22, wherein during the startup mode, the return valve begins to open once a pressure threshold is detected within the sub-atmospheric reservoir by the pressure sensor, and wherein once the return valve is fully open, the control valve bypass closes to stop liquid flow within the control valve bypass and to direct working fluid into the data center cooling system.

24. The sub-atmospheric direct liquid cooling supply system of claim 23, wherein the liquid ring pump is in auto control mode such that the liquid ring pump turns on upon receiving a top-level open signal and turns off upon receiving a top-level closed signal.

25. The sub-atmospheric direct liquid cooling supply system of claim 21, comprising:
a sub-atmospheric reservoir bypass line fluidically connected between the outlet of the data center cooling system and the inlet of the sub-atmospheric reservoir and to the pump, the sub-atmospheric reservoir bypass line configured to direct cooling liquid from the data center cooling system to the pump bypassing the sub-atmospheric reservoir.

26. The sub-atmospheric direct liquid cooling supply system of claim 25, wherein in the shutdown mode, the liquid ring pump is turned off, and a vent in the sub-atmospheric reservoir is opened to permit air into the sub-atmospheric reservoir, the sub-atmospheric reservoir bypass line is opened, the control valve bypass is opened, and the control valve is turned off.

27. The sub-atmospheric direct liquid cooling supply system of claim 26, wherein once the sub-atmospheric reservoir is mostly drained of liquid, the sub-atmospheric reservoir bypass line, the return valve, and the air vent are closed, the pump is stopped, and the control valve bypass is closed.

28. The sub-atmospheric direct liquid cooling supply system of claim 27, comprising a drain configured to be open upon shutdown of the sub-atmospheric direct liquid cooling supply system to drain liquid within the sub-atmospheric reservoir and permit the sub-atmospheric reservoir and the data center cooling system to reach atmospheric pressure.

29. A method of sub-atmospheric direct liquid cooling for a sub-atmospheric direct liquid cooling supply system, the method comprising:
receiving and storing, with an atmospheric reservoir, a cooling liquid from a cooling liquid source;
directing the cooling liquid from the atmospheric reservoir to an inlet of a data center cooling system;
receiving, with an inlet of a sub-atmospheric reservoir, the cooling liquid from an outlet of the data center cooling system;
controlling an inlet pressure at the inlet of the data center cooling system with a control valve, the control valve installed between the atmospheric reservoir and the inlet of the data center cooling system; and
controlling an outlet pressure at the outlet of the data center cooling system with a pump, an inlet of the pump fluidically connected to an outlet of the sub-atmospheric reservoir, the inlet pressure of the data center cooling system being greater than the outlet pressure of the data center cooling system.

30. The method of claim 29, wherein controlling the outlet pressure at the outlet of the data center cooling system further comprises:
decreasing a pressure of the sub-atmospheric reservoir via a liquid ring pump fluidically connected to an air vent of the sub-atmospheric reservoir to draw air out of the sub-atmospheric reservoir.

31. The method of claim 30, wherein controlling the outlet pressure at the outlet of the data center cooling system further comprises:
monitoring, with a top-level liquid switch, a liquid level within the sub-atmospheric reservoir, the top-level liquid switch configured to generate a top-level open signal and a top-level closed signal, the top-level open signal indicative of the cooling liquid within the sub-atmospheric reservoir being below a pre-determined maximum level, the top-level closed signal indicative of the cooling liquid within the sub-atmospheric reservoir being at or above the pre-determined maximum level; and
monitoring, with a low-level liquid switch, a liquid level within the sub-atmospheric reservoir, the low-level liquid switch configured to generate a low-level open signal and a low-level closed signal, the low-level open signal indicative of the cooling liquid within the sub-atmospheric reservoir is below a pre-determined minimum level, the low-level closed signal indicative of the cooling liquid within the sub-atmospheric reservoir being at or above the pre-determined minimum level.

32. The method of claim 31, wherein the sub-atmospheric direct liquid cooling supply system comprises a startup mode, a standard operating mode, and a shutdown mode.

33. The method of claim 32, wherein the startup mode comprises:
opening a control valve bypass, the control valve bypass having an inlet fluidically connected between the atmospheric reservoir and the control valve and an outlet fluidically connected between the sub-atmospheric reservoir and the pump;
opening, at least partially, a second control valve, the second control valve fluidically connected between the pump and the cooling liquid source and the atmospheric reservoir;
powering on the pump;
setting the control valve to an auto control mode to control the inlet pressure at the inlet of the data center cooling system to a pre-determined value; and
powering on the liquid ring pump to decrease pressure throughout the sub-atmospheric reservoir and the data center cooling system.

34. The method of claim 33, wherein the startup mode comprises:
receiving the low-level closed signal;
opening a return valve upon receiving the low-level closed signal, the return valve fluidically connected between the outlet of the sub-atmospheric reservoir and the pump and configured to fluidically connect or fluidically isolate the sub-atmospheric reservoir and the pump; and
closing the control valve bypass, on condition that the return valve is fully open, to stop flow of the cooling liquid within the control valve bypass and direct working fluid into the data center cooling system.

35. The method of claim 32, wherein the shutdown mode comprises:
powering off the liquid ring pump;
opening a vent in the sub-atmospheric reservoir to permit air into the sub-atmospheric reservoir;
opening a sub-atmospheric reservoir bypass line, the sub-atmospheric reservoir bypass line is fluidically connected between the outlet of the data center cooling system and the inlet of the sub-atmospheric reservoir and to the pump, the sub-atmospheric reservoir bypass line configured to direct cooling liquid from the data center cooling system to the pump bypassing the sub-atmospheric reservoir;
opening a control valve bypass, the control valve bypass having an inlet fluidically connected between the atmospheric reservoir and the control valve and an outlet fluidically connected between the sub-atmospheric reservoir and the pump; and
turning off the control valve.

36. The method of claim 32, wherein the shutdown mode comprises:
opening a drain of the sub-atmospheric reservoir, on condition that the sub-atmospheric direct liquid cooling supply system is shut down, to drain liquid within the sub-atmospheric reservoir and permit the sub-atmospheric reservoir and the data center cooling system to reach atmospheric pressure.
